(19) United States
(12) Patent Application Publication
(10) Pub. No.: US 2005/0090078 A1
(43) Pub. Date: Apr. 28, 2005

(54) Processing apparatus and method

(75) Inventor: Shigenori Ishihara, Ibaraki (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/766,865

(22) Filed: Jan. 30, 2004

(30) Foreign Application Priority Data
Oct. 22, 2003 (JP) 2003-362535

(51) Int. Cl. H01L 21/322; H01L 21/477; H01L 21/26

(52) U.S. Cl. 438/471; 438/474

(57) ABSTRACT

A processing method that uses process gas plasma that contains at least hydrogen to terminate dangling bonds in an object that at least partially contains a silicon system material includes the steps of placing the object on a susceptor in a process chamber that includes a dielectric window and the susceptor, and controlling a temperature of the susceptor to a predetermined temperature, controlling a pressure in the process chamber to a predetermined pressure, introducing the process gas into the process chamber, and introducing, via the dielectric window, microwaves for a plasma treatment to the object into the process chamber so that plasma of the process gas has plasma density of 10¹¹ cm⁻³ or greater, wherein a distance between the dielectric window and the object is maintained between 20 mm and 200 mm.

This application claims a benefit of priority based on Japanese Patent Application No. 2003-362535, filed on Oct. 22, 2003, which is hereby incorporated by reference herein in its entirety as if fully set forth herein.

### BACKGROUND OF THE INVENTION

The present invention relates generally to a semiconductor device manufacture, and more particularly to a plasma processing method and apparatus for terminating dangling bonds.

It has been known that a semiconductor device includes dangling bonds in a thin film interface in a silicon system material, a polycrystal silicon grain boundary, and a defect that results from plasma damages, and the dangling bonds negatively affect device performance or operations, such as carrier trap level and barriers to carrier movements. For example, it has also been known that the dangling bonds in a poly-silicon grain boundary attenuate ON current, increase OFF current and S value in a thin film transistor (“TFT”), and the defects between silicon and an oxide film increase dark current in the CCD.

Hydrogen-radical or hydric termination treatments to dangling bonds, such as annealing under a hydrogen gas atmosphere and a hydrogen plasma treatment that uses a RIE apparatus, etc., have been known as one effective solution for the above problems. See, for example, Japanese Patent Applications Publications Nos. 7-74167 and 4-338194, and Japanese Patent Publication No. 7-087250.

However, annealing under a hydrogen gas atmosphere disadvantageously has a low dangling-bond termination speed, and requires a long time for treatment. On the other hand, the hydrogen plasma treatment has high termination efficiency and can finish in a shorter time than the annealing. However, the conventional hydrogen plasma treatment uses a processing apparatus that typically places a substrate near a plasma generating region for high treatment efficiency, applies bias, and exposes the substrate to charged particles of high energy, as proposed in Japanese Patent Application Publication No. 4-338194, allowing plasma to damage a device, such as a shift of transistor's Vth (threshold voltage) and a creation of a new interface state.

### BRIEF SUMMARY OF THE INVENTION

Accordingly, it is an exemplary object of the present invention to provide a processing apparatus and method, which minimize plasma damages and provide efficient terminations.

A processing method of one aspect according to the present invention that uses process gas plasma that contains at least hydrogen to terminate dangling bonds in an object that at least partially contains a silicon system material includes the steps of placing the object on a susceptor in a process chamber that includes a dielectric window and the susceptor, and controlling a temperature of the susceptor to a predetermined temperature, controlling a pressure in the process chamber to a predetermined pressure, introducing the process gas into the process chamber, and introducing, via the dielectric window, microwaves for a plasma treatment to the object into the process chamber so that plasma of the process gas has plasma density of 10¹¹ cm⁻³ or greater, wherein a distance between the dielectric window and the object is maintained between 20 mm and 200 mm.

Preferably, the plasma treatment requires no bias application. The step of introducing the microwaves may previously regulate an output of a microwave generator that supplies the microwaves, so as to obtain the plasma density. The distance may be between 50 mm and 150 mm. The predetermined temperature may be between 200° C. and 400° C. The predetermined pressure may be between 13 Pa and 665 Pa. The step of controlling the pressure may include the steps of igniting plasma under a pressure higher than the predetermined pressure, and changing the pressure to the predetermined pressure after said igniting step. The dielectric window may have a thermal conductivity of 70 W/m·K or greater. The step of introducing the microwaves uses an antenna that has one or more slots to introduce the microwaves into the dielectric window. The process gas may include inert gas at least at the time of plasma ignition.

A processing apparatus of another aspect according to the present invention that provides a plasma treatment to and terminates dangling bonds in an object that at least partially contains a silicon system material includes a process chamber, connected to a microwave generator for supplying microwaves, which includes a dielectric window that allows the microwave from the microwave generator to be introduced into said process chamber, and a susceptor that supports the object, an introducing part for introducing process gas that contains at least hydrogen gas into the process chamber, a measurement part for measuring a plasma discharge state of plasma of the process gas, and a controller for comparing a measurement result by said measurement part with a reference value to maintain plasma density to be 10¹¹ cm⁻³ or greater, and for giving an alarm as abnormal discharge when determining that the plasma density becomes below 10¹¹ cm⁻³, wherein a distance between the dielectric window and the object is maintained between 20 mm and 200 mm.

Other objects and further features of the present invention will become readily apparent from the following description of the preferred embodiments with reference to accompanying drawings.

### BRIEF DESCRIPTION OF THE DRAWINGS

FIG. 1 is a schematic block diagram of a processing apparatus of one embodiment according to the present invention.

FIG. 2 is a graph showing a relationship between a distance from a dielectric window and an object shown in FIG. 1 and a resist film reduction speed by hydrogen plasma.

FIG. 3 is a graph showing a relationship between a temperature rise and a thermal conductivity of the dielectric window shown in FIG. 1 after plasma irradiation.

FIGS. 4A to 4E are plane views showing various shapes applicable to a slot antenna shown in FIG. 1.

FIG. 5 is a graph showing a relationship between the hydrogen plasma ignition and hydrogen gas pressure.

FIG. 6 is a view for explaining a cutoff phenomenon of microwaves caused by high-density plasma, FIG. 6A shows low-density plasma that does not generate cutoff, and FIG. 6B shows high-density plasma that generates cutoff.

FIG. 7 is a graph showing a relationship between a distance from the dielectric and microwave electric-field strength.

### DETAILED DESCRIPTION OF THE PREFERRED EMBODIMENTS

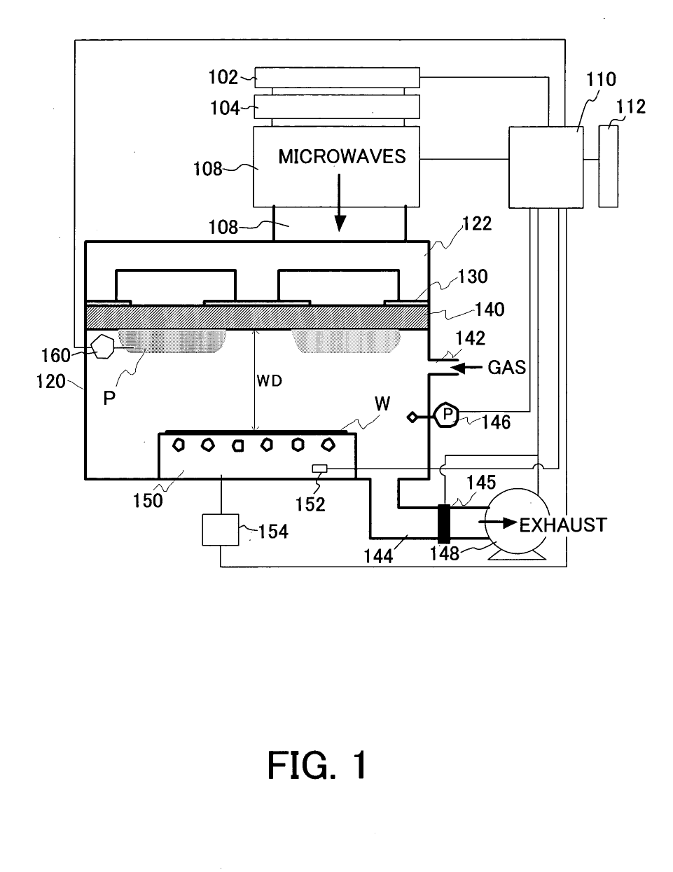

A detailed description will now be given of a plasma processing apparatus 100 of one embodiment according to the present invention with reference to accompanying drawings. Here, FIG. 1 is a schematic sectional view of the plasma processing apparatus 100. The plasma processing apparatus 100 includes a microwave oscillator (generator or source) 102, an isolator 104, a waveguide 106, an impedance matching unit 108, a controller 110, a memory 112, a vacuum container 120, a non-terminal circle waveguide 122, a slot antenna 130, a dielectric window 140, a process gas pipe 142, an exhaust pipe 144, a pressure sensor 146, a vacuum pump 148, a susceptor 150, a thermometer 152, a temperature control part 154, and a detector 160, and applies a plasma treatment to an object W that at least partially contains a silicon system material.

The microwave oscillator 102 is, for example, a magnetron and generates microwaves, for example, of 2.45 GHz. The microwaves are then converted by a mode converter into a TM, TE or TEM mode or the like, before propagating through the waveguide 106. The isolator 104 prevents microwaves reflected on the waveguide 106 etc. from returning to the microwave oscillator 102, and absorbs the reflected waves. The impedance matching unit 108, which is made of an EH tuner, a stab tuner, etc., includes a power meter that detects the strength and phase of each of a progressive wave supplied from the microwave oscillator 102 to the load and a reflected wave that is reflected by the load and returning to the microwave oscillator 102, and serves to match between microwave oscillator 102 and a load side.

The controller 110 controls operations of each component in the plasma processing apparatus 100 and, in particular, provides various controls, such as an output control of the microwave oscillator 102 based on data stored in a memory 112 to maintain the plasma density to a predetermined value, impedance control of the impedance matching unit 108, a pressure control in the vacuum container 120, and a temperature control for the susceptor 150.

The memory 112 stores data necessary for various controls. More specifically, the memory 112 stores a predetermined microwave output value designated by recipe to obtain the predetermined plasma density of 10¹¹ cm⁻³ or greater, and a permissible error range or error budget necessary to maintain the plasma density constant. For impedance control, the memory 112 also stores a relationship a tuner position region necessary for plasma ignition (which indicates stab's millimeter position and moving direction) and a tuner position region of the impedance matching unit 108 to minimize the reflected microwaves in the plasma treatment. The memory 112 also stores a predetermined pressure or pressure range between 13 Pa and 665 Pa for pressure control. The memory 112 also stores a predetermined temperature or temperature range between 200° C. and 400° C. for temperature control. The memory 112 basically stores values designated as recipes.

The vacuum container 120 is a process chamber that accommodates the object W and provides a plasma treatment to the object under a reduced pressure or vacuum environment. FIG. 1 omits a gate valve that receives the object W from and feeds the substrate 102 to a load lock chamber (not shown), and the like.

The non-terminal circle (or annular) waveguide 122 forms interference waves to microwaves supplied from the waveguide 106, and includes a cooling water channel (not shown).

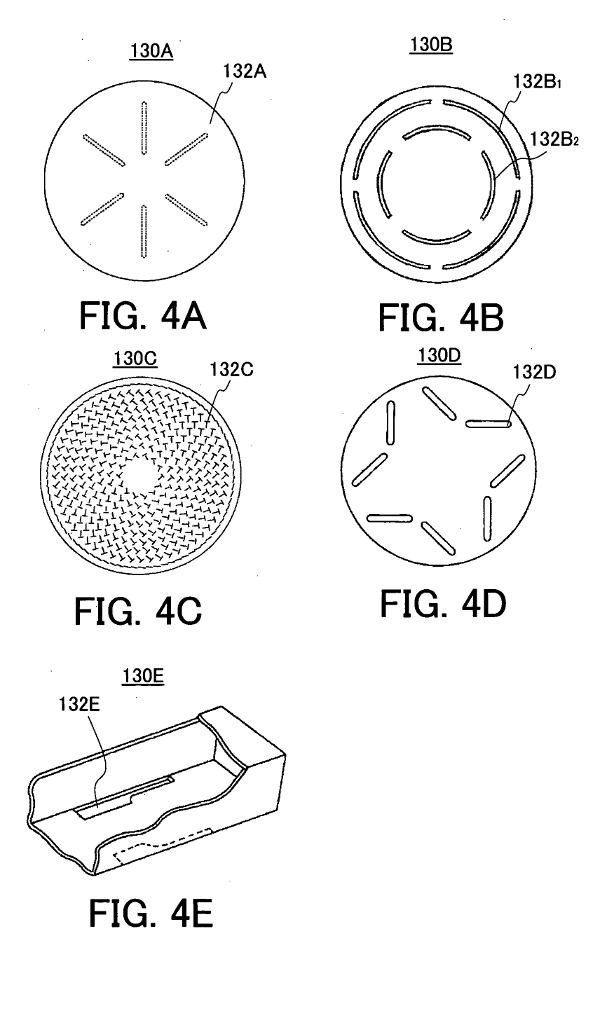

The slot antenna 130 forms surface interference waves on the surface of the dielectric window 140 at its vacuum side. The slot antenna 130 can use any of slot antenna 130A to 130E exemplarily shown in FIGS. 4A to 4E. The slot antenna 130A is a metal disc having six radial slots 132A. The slot antenna 130B is a metal disc having four circumferential, two-type slots 132B₁ and 132B₂. The slot antenna 130C is a metal disc having multiple concentric or spiral T-shaped slots 132C. The slot antenna 130C is a metal disc having four pairs of V-shaped slots 132D. Of course, the slot antenna 130 does not limit an antenna shape to a radial line slot antenna (“RLSA”), and can use other types of antennas, such as a rectangular waveguide 130E having slots 132E.

Importantly, a uniform treatment over the entire surface of the object W needs a supply of active species with good in-plane uniformity. The slot antennas 130A to 130E arrange at least one slot 132A to 132E, generates the plasma over a large area, and facilitates control over the plasma strength and uniformity. In the instant specification, a reference numeral with a capital designates a variation, and is generalized by the reference numeral without the capital.

The dielectric window 140 seals the vacuum in the vacuum container 120, transmits and introduces the microwaves to the vacuum container 120. A working distance WD between the dielectric window 140 and the object W is maintained preferably between 20 mm and 200 mm, more preferably between 50 mm and 150 mm.

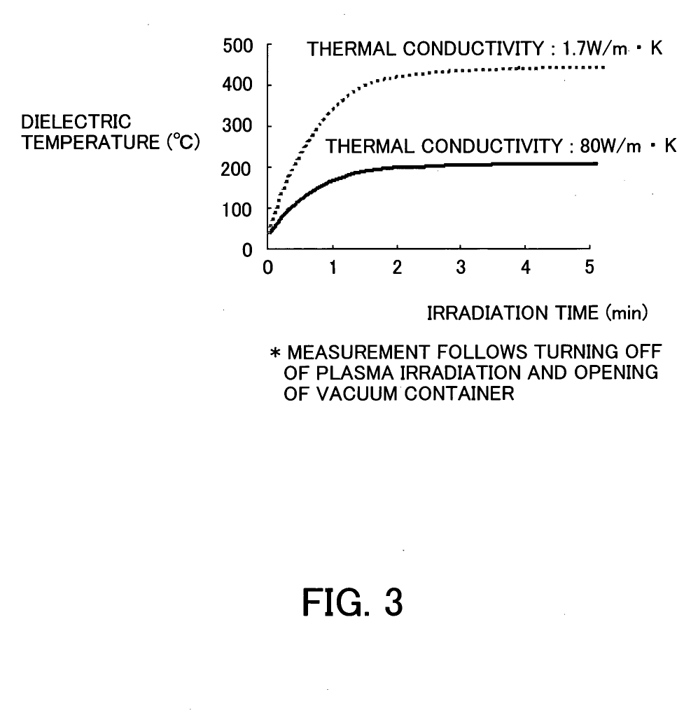

The dielectric window 140 is directly exposed to the plasma generating region. When the dielectric window 140 is made of a material with a low thermal conductivity, the excessively heated dielectric window may possibly result in an excessive temperature rise of the object W indirectly. FIG. 3 shows data indicative of a temperature rise in the dielectric window subject to the hydrogen plasma irradiation, which is measured after the plasma irradiation ends and the vacuum container opens. Since the measurement follows opening of the vacuum container, the temperature during the irradiation is assumed to be higher. Use of the dielectric window 140 made of a material having a thermal conductivity of 70 W/m·K or greater, such as aluminum nitride, would reduce the dielectric temperature down to 300° C. or lower even during the plasma irradiation, and prevent the reduced treatment efficiency due to the excessively heated object W.

The process gas pipe 142 is part of gas supply means, and connected to the vacuum container 120. The gas supply means includes a gas source, a valve, a mass flow controller, and the gas pipe 142 that connects them, and supplies process gas and discharge gas to be excited by the microwaves for predetermined plasma. The process gas contains at least hydrogen gas in the instant embodiment, and may add inert gas, such as Xe, Ar and He for prompt plasma ignitions at least at the ignition time. The inert gas is not reactive and does not negatively affect the object W. The inert gas ionizes easily, and improves plasma ignitions at the time of microwave introduction.

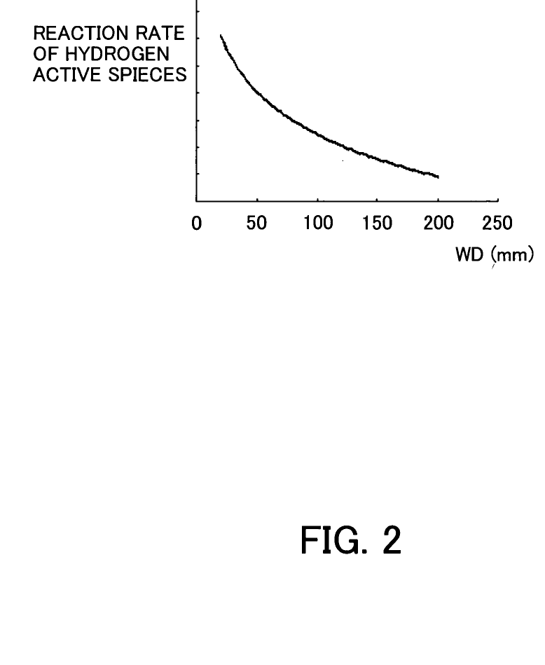

Here, the hydrogen active species become inactive due to collisions between molecules when transported from the plasma generating region. Therefore, the density of the hydrogen active species that reach the object W greatly relies upon the working distance WD between the dielectric window 140 and the susceptor 150, which will be described later. FIG. 2 is a graph showing a relationship between WD and a film reduction speed caused by reduction when the hydrogen plasma is irradiated onto an organic material used as resist. As indicated, a smaller WD would make higher the density of the hydrogen active species that reaches the object W.

However, a WD smaller than 20 mm is not preferable because the object W becomes too close to the plasma generating region P and gets damaged by the hydrogen active species with the excessively high energy. Therefore, WD is preferably between 20 mm and 200 mm for effective termination treatment, and more preferably 50 mm and 150 mm to reconcile the high process efficiency and low damages.

The exhaust pipe 144 is connected to the bottom of the vacuum container 120, and a vacuum pump 148. The exhaust pipe 144, pressure control valve 145, pressure sensor 146, vacuum pump 148 and controller 110 constitute a pressure control mechanism. In other words, the controller 110 controls the pressure in the vacuum container 120 by controlling opening of the pressure control valve 145, such as a VAT Vakuumventile A.G. (“VAT”) manufactured gate valve that has a pressure regulating function and an MKS Instruments, Inc. (“MKS”) manufactured exhaust slot valve, so that the pressure sensor 146 for detecting the pressure in the vacuum container 120 detects a predetermined value. As a result, the pressure control mechanism controls the internal pressure of the vacuum container 120 to be a desired pressure between 13 Pa and 665 Pa. The vacuum pump 148 includes, for example, a turbo molecular pump (TMP), and is connected to the vacuum container 120 via the pressure control valve (not shown), such as a conductance valve.

The susceptor 150 is accommodated in the vacuum container 120, supports the object W, and its temperature is controlled to a desired temperature between the 200° C. and 400° C. by the temperature control part 154, such as a heater. The controller 110 controls operations of the temperature control part 154. The controller 110 controls, for example, electrification from a power source (not shown) to a heater line so that the temperature detected by the thermometer 152 becomes a predetermined temperature. Instead of detecting the temperature of the susceptor 150, the temperature of the object W can be indirectly detected (for example, by using radiant heat to detect the temperature of the object W).

The detector 160 is plasma light intensity measuring means for measuring the plasma discharge state, such as Q-MAS and a Langmuir probe, and monitors whether the plasma density is within a normal range. The plasma light intensity measuring means includes a wavelength selecting means, such as an optical filter and a prism, and a photoelectric conversion element, and measures the light intensity of excited hydrogen atoms, such as 486 nm and 655 nm. The plasma measurement probe, such as a Langmuir probe, measures current that results from ions and electrons in plasma. Q-MAS takes in plasma excited gas in a detector, and uses a mass analyzer to measure the strength of the hydrogen active species.

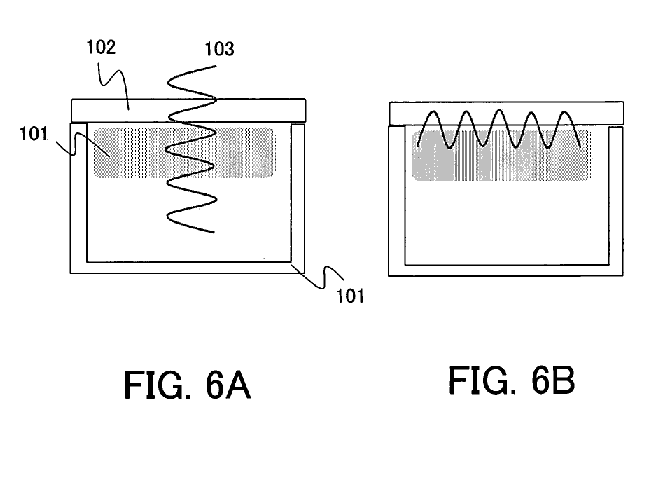

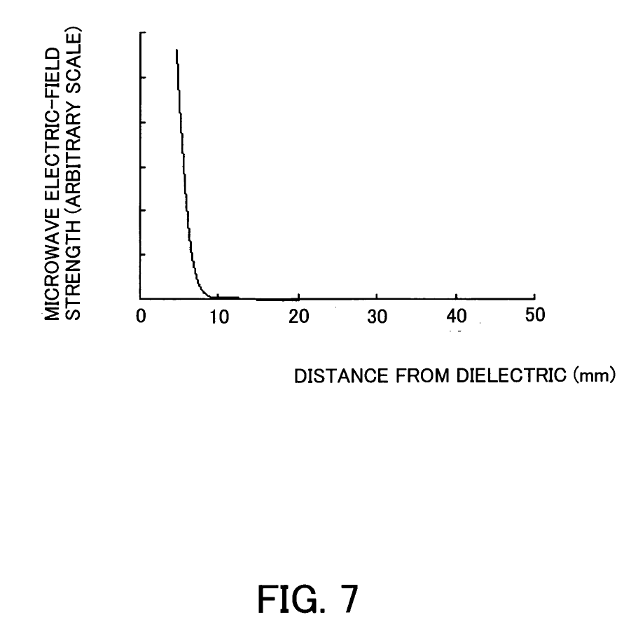

A description will be given of operations of the processing apparatus 100. The gas supply means opens a valve (not shown) and introduces the process gas that contains hydrogen gas into the vacuum container 120 through the process gas pipe 142 through the mass flow controller. Cooling water is supplied to the cooling water channel (not shown) to cool the non-terminal circular waveguide 122. The controller 110 determines whether a measurement value of the plasma discharge state detected by the detector 160 is within a predetermined range stored in the memory 112. When the controller 110 compares this value with the reference value and determines that it is outside the predetermined range, the controller 110 gives an alarm by considering that the abnormal discharge lowers the plasma density, or monitors and maintains an output of the microwave oscillator to be recipe designated value so that the plasma density during processing can be within the predetermined range. When the plasma density is higher than a predetermined value (for example 7×10¹⁰ cm⁻³ in case of microwaves of 2.45 GHz), a phenomenon called “cutoff” (see FIG. 6) allows the microwaves to propagate only in the surface direction of the dielectric window 140 and produce so-called surface waves, and does not allow the microwaves to propagate in the down direction. Since the electric field exists only on the dielectric surface (see FIG. 7), the plasma generation region P is limited near the dielectric window.

As a result, the microwave oscillator 102 supplies the microwaves to the vacuum container 120 via the non-terminal annular waveguide 122 and the dielectric window 140, and generates the plasma in the vacuum container 120. Microwaves introduced into the non-terminal annular waveguide 122 separates in two, i.e., left and right, directions, propagate with an in-tube wavelength longer than that in the free space, introduced into the vacuum container 120 via the dielectric window 140 through the lots 132, and transmit as a surface wave on the surface of the dielectric window 140. This surface wave interferes between adjacent slots 132, and forms an electric field. This electric field generates high-density plasma. The plasma generating region P has the high electron density and allows hydrogen to effectively get isolated. The electron temperature rapidly lowers as a distance from the plasma generation part increases, lowering damages to the device. The active species in the plasma are transported to and near the substrate 102 through diffusion, etc., and reach the surface of the substrate 102.

In the impedance control, the controller 110 detects the strength and phase of the reflected microwaves input from the impedance matching unit 108 at the load side, and controls the impedance matching unit 108 so that this reflected waves are minimized. The matching position of the impedance matching unit 108 is a matching state in which the reflected waves are minimized after the plasma generates.

In the pressure control, the controller 110 controls the pressure control valve 145 through feedback control, etc., so that the pressure detected by the pressure sensor 146 can be approximately maintained to be a preset value. The preset pressure value is preferably between 13 Pa and 655 Pa. Hydrogen gas has an ionization cross section smaller than oxygen and nitrogen, and exhibits bad plasma ignition performance. Therefore, the excessively low pressure below 13 Pa would make treatments unstable. In addition, the generated hydrogen active species have such a long mean free path that the active species with the energy higher than expected may possibly reach the object W. Therefore, the device may get damaged although the damage level is lower than that where the charged particles are injected into the object W by a bias application or where the object W is exposed directly to the plasma generating region P. Conversely, the excessively high pressure above 655 Pa would possibly make the hydrogen active species inactive before they reach the object W.

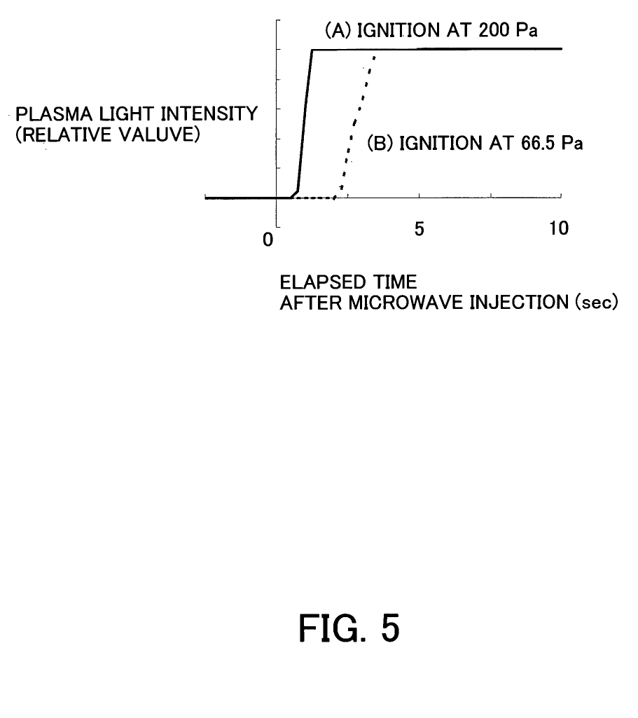

Since hydrogen gas has an ionization cross section smaller than oxygen and exhibits bad plasma ignition performance, a time lag occurs between the microwave injection and plasma ignition. In this case, pressure higher than the process pressure (although the pressure is between 13 Pa and 655 Pa), as shown in FIG. 5, can stabilize the plasma ignition and maintain the process repeatability. An addition of inert gas that relatively effectively promotes the plasma ignition would also effectively improve the process repeatability.

In the temperature control, the controller 110 controls the temperature control part 154 so that the temperature of the susceptor 150 detected by the thermometer 152 can be approximately maintained to be the preset value. The preset temperature value is preferably between 200° C. and 400° C. The process temperature below this restrains hydrogen active species that have reached a surface of the object W from diffusing in the device, whereas the process temperature above this causes desorptions of hydrogen from the hydrically terminated object W and deteriorates the treatment efficiency, for example, as pointed out by Japanese Patent Publication No. 7-87250.

Then, the controller 110 introduces the microwaves with a predetermined output into the vacuum container 120, and generates the electric field on the dielectric window 140. The electric field formed on the dielectric window 140 and process gas that contains at least hydrogen gas introduced from the process gas pipe 142 generate high-density plasma of 10¹¹ cm⁻³ or greater only near the dielectric window 140. The object W heated up to the predetermined temperature on the susceptor is hydrically terminated by the hydrogen active species transported on the susceptor 150 by a gas flow from the plasma generating region P. As a result, dangling bonds are recovered. The instant embodiment can create extremely high plasma density and obtain sufficient process efficiency without a bias application to the object W to inject the charged particles into the object W.

The plasma generating region P is limited only near the dielectric window 140, and the working distance WD is 20 mm or greater. In other words, since the object W is processed sufficiently distant from the plasma generating region P, the device is less subject to plasma damages than the prior art. Since this can restrain generations of new defects and Vth shifts associated with the plasma treatment, which might cancel the termination treatment effects, the plasma processing apparatus 100 can provide a high-quality plasma termination treatment to the object W.

The impedance matching unit 108 generates plasma from microwaves in a short time, and the controller 110 subsequently controls the operations of the impedance matching unit 108 to maintain the matching position. As a result, the microwaves are efficiently introduced into the vacuum container 120, and the plasma processing apparatus 100 can maintain the high-density plasma treatment. The plasma treatment is conducted for a preset time period.

First Embodiment

This embodiment used the processing apparatus 100 and the above processing method to hyrically terminate poly-Si TFT formed on a quartz substrate. The working distance WD between the dielectric window 140 and the susceptor 150 was set 100 mm, and the process conditions set the substrate temperature to be 275° C., gas to be 100% hydrogen, the gas pressure to be 66.5 Pa, and the microwave output to be 3 kW. As a result, only tem-minute treatment could not only provide effects, such as a S-value reduction effect, similar to that of the conventional RIE apparatus working for 30 minutes, but also restrain damages to the device in a low or indifferent level.

Thus, the processing apparatus 100 forms the high-density plasma only near the dielectric window 140, and provides a plasma treatment to the object W using diffusions from the high-density plasma, without exposing the object W to the plasma generating region P. In addition, the processing apparatus 100 does not apply bias to inject charged particles into the object W. Therefore, the processing apparatus 100 can provide an efficient hydric termination treatment with little damages, and a simple apparatus structure.

The present invention can provide a processing apparatus and method, which minimize plasma damages and provide efficient terminations.

1. A processing method that uses process gas plasma that contains at least hydrogen to terminate dangling bonds in an object that at least partially contains a silicon system material, said processing method comprising the steps of:
placing the object on a susceptor in a process chamber that includes a dielectric window and the susceptor, and controlling a temperature of the susceptor to a predetermined temperature;
controlling a pressure in the process chamber to a predetermined pressure;
introducing the process gas into the process chamber; and
introducing, via the dielectric window, microwaves for a plasma treatment to the object into the process chamber so that plasma of the process gas has plasma density of 10¹¹ cm⁻³ or greater, wherein a distance between the dielectric window and the object is maintained between 20 mm and 200 mm.

2. A processing method according to claim 1, wherein the plasma treatment requires no bias application.

3. A processing method according to claim 1, wherein said step of introducing the microwaves previously regulates an output of a microwave generator that supplies the microwaves, so as to obtain the plasma density.

4. A processing method according to claim 1, wherein the distance is between 50 mm and 150 mm.

5. A processing method according to claim 1, wherein the predetermined temperature is between 200° C. and 400° C.

6. A processing method according to claim 1, wherein the predetermined pressure is between 13 Pa and 665 Pa.

7. A processing method according to claim 1, wherein said step of controlling the pressure includes the steps of:
igniting plasma under a pressure higher than the predetermined pressure; and
changing the pressure to the predetermined pressure after said igniting step.

8. A processing method according to claim 1, wherein the dielectric window has a thermal conductivity of 70 W/m·K or greater.

9. A processing method according to claim 1, wherein said step of introducing the microwaves uses an antenna that has one or more slots to introduce the microwaves into the dielectric window.

10. A processing method according to claim 1, wherein the process gas includes inert gas at least at the time of plasma ignition.

11. A processing apparatus that provides a plasma treatment to and terminates dangling bonds in an object that at least partially contains a silicon system material, said processing apparatus comprising:
a process chamber, connected to a microwave generator for supplying microwaves, which includes a dielectric window that allows the microwave from the microwave generator to be introduced into said process chamber, and a susceptor that supports the object;
an introducing part for introducing process gas that contains at least hydrogen gas into the process chamber;
a measurement part for measuring a plasma discharge state of plasma of the process gas; and
a controller for comparing a measurement result by said measurement part with a reference value to maintain plasma density to be 10¹¹ cm⁻³ or greater, and for giving an alarm as abnormal discharge when determining that the plasma density becomes below 10¹¹ cm⁻³, wherein a distance between the dielectric window and the object is maintained between 20 mm and 200 mm.
